(19) United States
(12) Patent Application Publication
(10) Pub. No.: US 2006/0008943 A1
(43) Pub. Date: Jan. 12, 2006

(54) Mounting semiconductor chips

(76) Inventor: Berthold Hahn, Hemau (DE)

Correspondence Address: FISH & RICHARDSON P.C., PO BOX 1022, MINNEAPOLIS, MN, 55440-1022, US

(21) Appl. No.: 11/174,007

(22) Filed: Jun. 30, 2005

(30) Foreign Application Priority Data
Jun. 30, 2004 (DE) 10 2004 031 734.8
Sep. 13, 2004 (DE) 10 2004 044 179.0

(51) Int. Cl. H01L 21/44

(52) U.S. Cl. 438/107

(57) ABSTRACT

To mount semiconductor chips (3), the chips are placed in a liquid (5), and drops (51) of the liquid containing no more than one semiconductor chip are positioned on a substrate (2). On the substrate are molecules of a first type (1), on the semiconductor chips (3) are molecules of a second type (4) which can bond with the molecules of the first type (1). After the liquid (5) dries, the semiconductor chip (3) can be electrically contacted on the substrate (2) by conductive structures (21).

### CROSS-REFERENCE TO RELATED APPLICATIONS

This application claims the benefit of priority under 35 U.S.C. §119 to German application serial number 10 2004 031 734.8, filed Jun. 30, 2004, and to German application serial no. 10 2004 044 179.0, filed Sep. 13, 2004.

### BACKGROUND

The invention relates to mounting of semiconductor chips. The continuing trend toward miniaturizing semiconductor chips has made it necessary to develop new mounting methods that are adapted to the special demands generated by the small dimensions of the semiconductor chips to be mounted. To facilitate such mounting methods, the design of the semiconductor chips may have to be altered.

In particular, the difficulties of maintaining precise mounting tolerances increase with the miniaturization of the semiconductor chips. In general, the precision of the mounting processes depends on the precision of the machines used to mount the chips, such as pick-and-place machines, bonding machines or wafer sawing machines. Problems can arise with alignment precision when positioning very small semiconductor chips with pick and place machines. If the dimensions of the semiconductor chips are outside of specific limits, such conventional machines can no longer be used.

Another problem is electrically contacting very small semiconductor chips to a contact site. The positioning precision and the size of the contact site also depends on the tolerances of the mounting device, such as a wire or ball bonder. In addition, short circuits can easily occur given the very small distances between the semiconductor chips.

Furthermore, the mechanical stress experienced by semiconductor chips when handled by conventional machines is not appropriate for very small semiconductor chips. The mechanical stress can lead to breakage or damage during the mounting process.

The tolerances for cutting apart the chips, e.g., dicing, are also determined by the precision of the mounting machine. Importantly, material is lost when smaller semiconductor chips are cut apart with conventional machines, such as a wafer sawing machine.

A method for the simplified manufacture of thin-film LED chips is disclosed in U.S. Publication No. 20040099873. To manufacture thin-film semiconductor chips, a sequence of active epitaxy layers is grown on a substrate with rear contact layers that are reinforced by a reinforcing layer. Then, an auxiliary substrate layer is applied, which enables the active sequence of epitaxy layers to be handled. The reinforcing layer and auxiliary substrate replace the mechanical substrate used in conventional manufacturing methods. However, this document does not provide any approach for mounting the semiconductor chips.

One goal is to present a method for mounting semiconductor chips on a substrate in which the semiconductor chips can be sequentially positioned as desired on the substrate.

### SUMMARY

In one aspect, the invention is directed to mounting semiconductor chips onto a substrate. Molecules of a first type are applied on the substrate surface on which the semiconductor chips are to be mounted. Molecules of a second type that can bond to the first molecules are applied to the surface of each semiconductor chip. The semiconductor chip is introduced into a liquid. A drop of liquid having no more than one semiconductor chip is positioned on the substrate. The drops of liquid on the substrate are evaporated, leaving the semiconductor chip on the substrate.

Particular implementations of the invention may include one or more of the following features. The semiconductor chip can be electrically contacted to the substrate with an electrically conductive structure. The semiconductor chip can be applied to a soluble auxiliary substrate and introduced into the liquid by dissolving the auxiliary substrate. The liquid can contain the molecules and the molecules can adsorb onto the semiconductor chip after the semiconductor chip is introduced into the liquid. The molecules can be applied to the semiconductor chip or the substrate by stamping, printing or photolithography. The molecules can be adsorbed on the substrate from a solution. The drop with the chips can be deposited on the substrate by an inkjet system. A cell sorting system can ensure that not more than one semiconductor chip is in a drop. Metal-containing particles can be added to the liquid with the semiconductor chip and the particles can electrically connect the semiconductor chips with electrically conductive structures of the substrate after the liquid dries. Parts of the surfaces of the substrate and chip can be modified to be more effectively wetted than other parts of the surface. The semiconductor chip can be a thin-film LED chip.

The method can also include manufacturing thin-film LED chips. An active layer sequence is formed on a substrate suitable to generate electromagnetic radiation. An electrically conductive reflective contact layer is at least partially formed on the active layer sequence. The active layer sequence is structured into separate, active stacks of layers on the substrate, forming gaps. An electrically conductive reinforcing layer is applied on the conductive reflective contact layer. A passivation layer is formed on the side surfaces of the active stacks and the reflective contact layer (the thin-film LED chip) and the electrically-conductive reinforcing layer. The gaps between the thin-film LED chips are filled with a filler. An auxiliary substrate layer is applied on the side of the thin-film LED chips opposite from the substrate. The substrate and filler are removed from between the LED chips. An electrically conductive layer is applied on one side of the thin-film LED chips.

The methods described herein may include one or more of the following advantages. The semiconductor chips may be positioned individually on the substrate, and the position of the respective semiconductor chip can hence be freely selected. The semiconductor chips' position may be finely adjusted on the substrate by short-range forces between the molecules of the first and second type. This can enable high mounting precision.

The method may be particularly suitable for mounting semiconductor chips with edge lengths less than or equal to 200 nm. The smaller the semiconductor chip, the easier it may be to mount the chip using the methods described herein as compared to conventional mounting methods. The methods described herein may be applicable to mounting chips on conventional standard lead frames, as well as on printed circuit boards.

In one implementation, metal-containing particles can be added to the liquid containing the semiconductor chips. The particles are deposited on the sides of the semiconductor chips when the liquid dries, forming electrically conductive structure. These electrically conductive structures then contact the substrate and form an electrical connection between the semiconductor chip and the substrate.

The metal-containing particles can be used for the electrical contacting of the semiconductor chip. Thus, the mounting precision is no longer affected by the precision of the bonding machine. In addition, bond pads need not be used to mount the semiconductor chip. Eliminating bond pads can eliminate shadow effects that can arise with very small chips.

In some implementations, the surface of the substrate is modified so that parts of the surface are wetted more effectively than the rest of the surface by the liquid containing the semiconductor chips. If the drops holding a single semiconductor chip are positioned on this part of the substrate surface, the drops' movement may be largely restricted to this part of the surface. Furthermore, the properties of parts of the semiconductor chip surfaces can be modified to wet more effectively than the rest of the surface by the fluid in which the semiconductor chips are introduced. The semiconductor chips thereby become automatically oriented in the liquid with the mounting side facing the substrate.

### BRIEF DESCRIPTION OF THE DRAWINGS

FIGS. 1a to 1f each show a schematic of the semiconductor chips and/or substrates at different stages in a mounting process.

FIGS. 2a to 2c each show a schematic of the semiconductor chips and/or substrates at different stages of the mounting process.

FIGS. 3a to 3c show a schematic of an implementation of the method of bonding.

FIGS. 4a and 4b show a schematic representation of the surface modification of a semiconductor chip and a substrate.

FIGS. 5a to 5i show cross-sectional side views of a thin-film LED chip and/or a substrate at different stages of a manufacturing process.

FIG. 6a shows a cross-sectional side view of the thin-film LED chip.

FIG. 6b shows a plan view of a thin-film LED chip.

In the exemplary embodiments and figures, the same or equivalent components are provided with the same reference number. The portrayed elements of the figures and especially the sizes of the portrayed molecules or layer thickness are not to scale. For the sake of clarity, they can in fact be partially enlarged.

### DETAILED DESCRIPTION

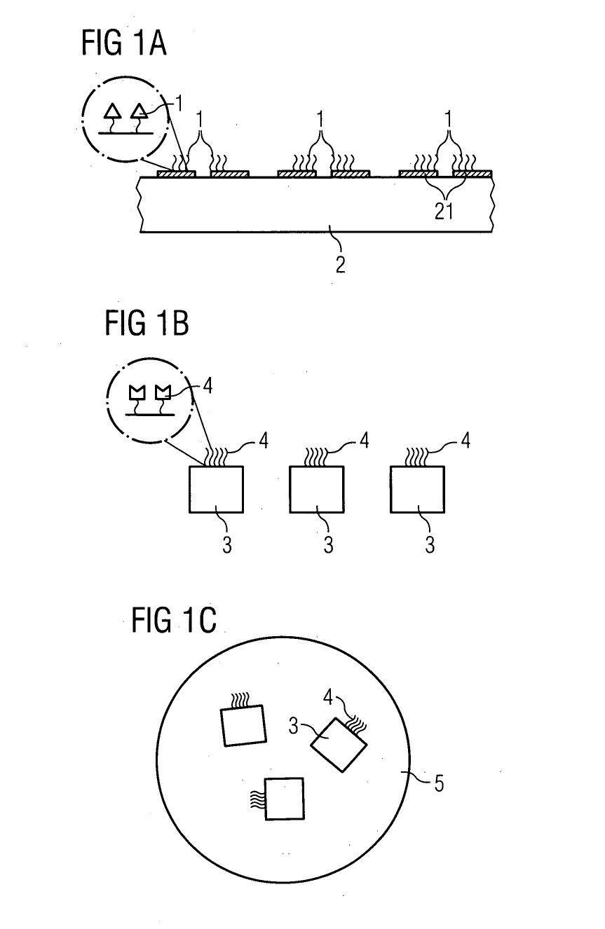

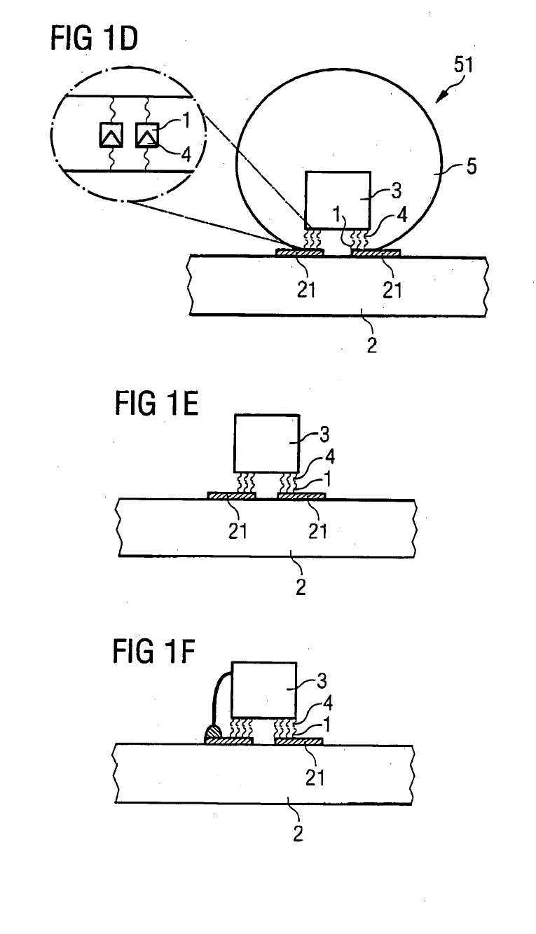

FIG. 1a shows a section of a substrate 2, such as a printed circuit board, whose surface is coated with molecules of a first type 1 at sites where a semiconductor chip 3 is to be mounted. The semiconductor chips 3 and molecules of a second type 4 are shown in FIG. 1b. The substrate 2 is provided with conductive structures 21, such as conductor paths, for electrically contacting the applied semiconductor chips 3 at a later stage of processing.

As shown in FIG. 1b, parts of the chip surface are coated with a second type 4 of molecule. The molecules of the first type 1 and second type 4 can bind to each other selectively or specifically. The molecules of the first type 1 can include molecules with one or more functional side groups that can form a specific bond with one or more functional side groups of the molecules of the second type 4. Complementary DNA strands that hybridize by forming hydrogen bridge bonds between the base pairs adenine/thymine and cytosine/guanine are just one example of such molecules. Alternatively, two different types of proteins or peptides can be used that form a specific bond based on the lock-and-key principle. Other functional groups that can be joined to a desired molecule and form a bond include thiols that bind to gold, and amino groups that bind to glass.

The molecules of the first type 1 and the second type 4 can be applied to the substrate 2 or the semiconductor chip 3 by being adsorbed from a solution, or by printing, such as screen printing or microcontact printing, or stamping. In some implementations, the second type 4 of molecules are applied onto the semiconductor chips by a printing process, stamping process or photolithographic process. This allows the semiconductor chips 3 to be easily coated with the second type 4 of molecules in a structured manner.

Referring to FIG. 1c, after coating the molecules onto the substrate 2 or semiconductor chip 3, the semiconductor chips 3 are introduced into a liquid 5.

Referring to FIG. 1d, one drop 51 of liquid 5 is positioned on the surface of the substrate 2. Positioning the drop 51 of liquid 5 aligns the semiconductor chip 3. In some implementations, the liquid 5 containing the semiconductor chips 3 is introduced into an inkjet system. In one implementation, the inkjet system forms drops 51 with no more than one semiconductor chip. A cell sorting system can ensure that there is not more than one semiconductor chip in each drop. The cell sorting system can be used to monitor the number of semiconductor chips 3 in a drop 51. The inkjet system can precisely position the individual drops, which contain no more than one semiconductor chip per drop.

The molecules of the first type 1 and second type 4 bind to each other.

Referring to FIG. 1e, the liquid is dried, such as by drying the substrate in an oven, placing the substrate under vacuum, or by drying the substrate under a nitrogen stream.

Referring to FIG. 1f, an electrical contact is established between the semiconductor chips 3 and an electrically conductive structure 21 on the substrate 2, such as by a wire bonding process.

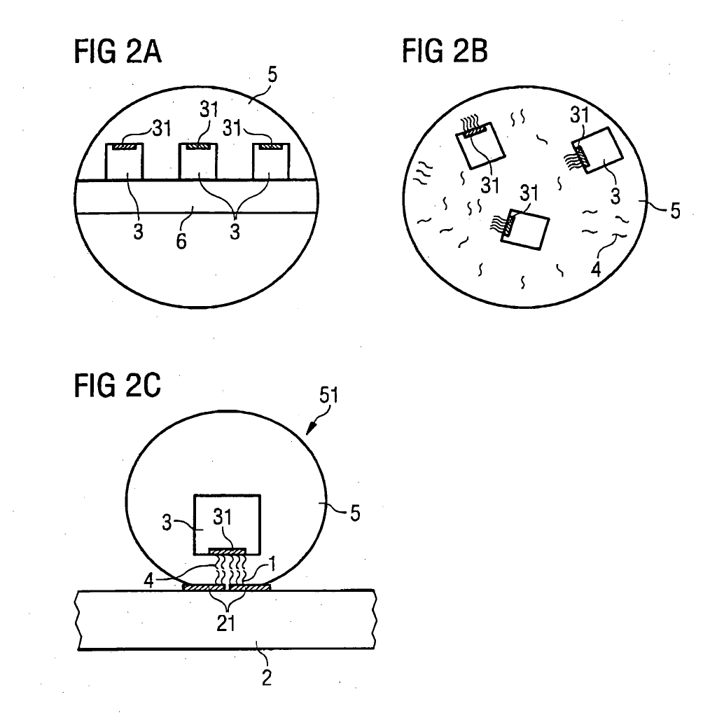

Referring to FIG. 2a, in some implementations, an auxiliary substrate is used in the bonding process. The semiconductor chips 3 are disposed on an auxiliary substrate 6. Referring to FIG. 2b, the semiconductor chips 3 are introduced into the liquid 5 by placing the auxiliary substrate in the liquid and dissolving the auxiliary substrate 6. Suitable materials, such as plastics, etchable metals, foils, including thermo release foils, ITO, molybdenum, and chemically reactive semiconductor materials, including zinc oxide or germanium, are selected for the auxiliary substrate 6 and liquids that can dissolve or remove the auxiliary substrate are selected for liquid 5. In one embodiment, the auxiliary substrate 6 includes ZnO and the liquid 5 includes an acid or ammonium chloride. In one embodiment, the auxiliary substrate 6 includes Ge and the liquid 5 includes an HF/hydrogen peroxide system. Other combinations of liquids and auxiliary substrates that dissolve in the liquids can also be used. A thermo release foil need not be dissolved in liquid, but can be removed by heating.

In some implementations, the chips 3 are coated with the molecules of the second type 4 by adding the molecule to the liquid 5 containing the semiconductor chips 3. Given a suitable liquid, the second type of molecules disperse in the liquid and are adsorbed at least on parts of the chip surface. The semiconductor chip 3 absorbs the molecules from the liquid 5. The semiconductor chips can be coated quickly and easily with the second type of molecules after the semiconductor chips are introduced into the liquid.

A technique using an auxiliary substrate can eliminate the need for handling the semiconductor chips individually to introduce the chips into the liquid. Thus, the chips may be exposed to reduced or only a small amount of mechanical stress. In addition, this technique may be suitable for virtually any sized semiconductor chip.

Referring to FIGS. 2a-c, to coat the semiconductor chips 3 or substrates 2 with molecules of the first type 1 or the second type 2 at specific sites 31 by adsorption from the solution, the respective surfaces at these sites 31 can be modified. If a gold coating is applied to site 31, molecules bearing a thiol group can bind to the gold. Likewise, amino groups can bind to a glass coating. Another functional group on the second type 4 of molecules may be needed to form a bond to the first type 1 of molecules for mounting.

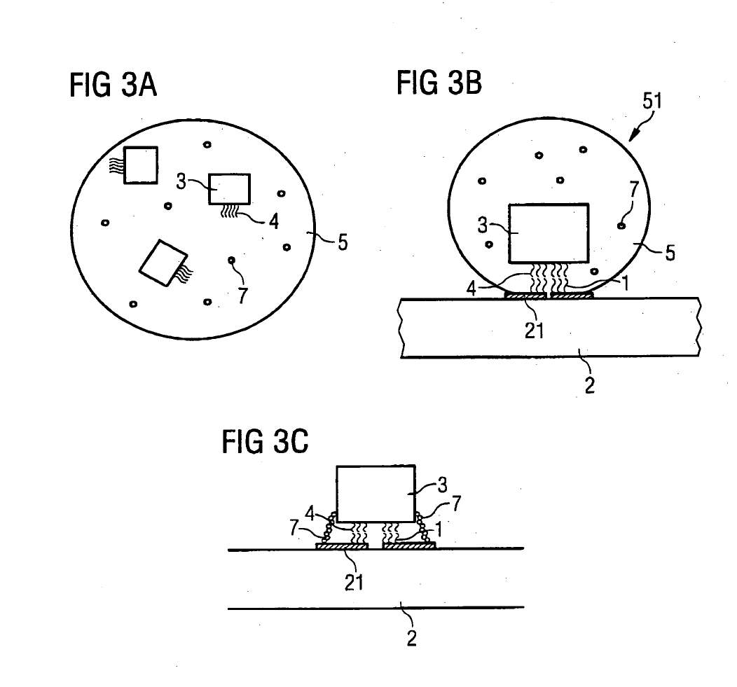

Referring to FIGS. 3a to 3c, an alternative manner of contacting the semiconductor chip 3 includes using metal-containing particles 7. After the semiconductor chips 3 are introduced into the liquid 5, metal-containing particles 7 are added to the liquid 5. The metal-containing particles 7 can be metal-containing molecules or metal-containing molecular aggregates, such as micelles or lipid vesicles. As described above, a drop 51 is formed containing just one semiconductor chip 3, and the drop 51 is positioned on the surface of the substrate 2. When the liquid 5 dries, the metal-containing particles 7 are deposited on the outside surface the chip 3 and create an electrical contact to the chip 3 if a correspondingly conductive structure 21 is on the substrate 2. Optionally, a substrate 2 with the pre-mounted semiconductor chips 3 can be coated in an electroless plating procedure to reinforce the electrical contacts and increase the mechanical stability of the overall system.

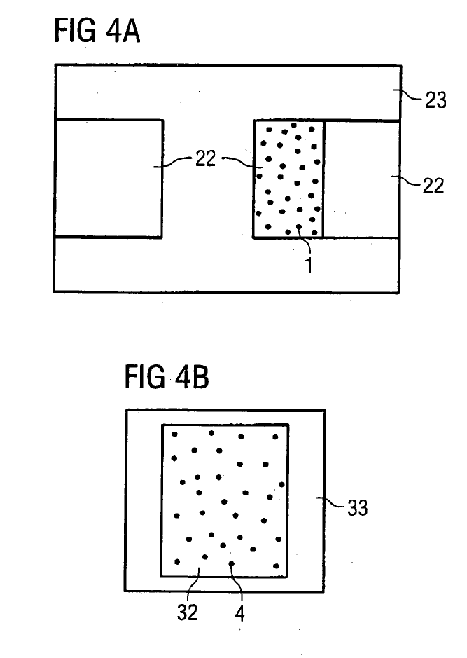

Referring to FIG. 4a, mounting areas 22 of the surface of the substrate 2 on which a semiconductor chip 3 is subsequently mounted can be modified so that the surface is wetted more effectively by the liquid 5 compared to the rest of the substrate surface 23. If a drop 51 of the liquid 5 containing a semiconductor chip 3 is positioned on the area 22, the drop 51 is restricted to this area and does not wet the rest of the surface.

Referring to FIG. 4b, for the semiconductor chip 3 to be automatically aligned properly in the liquid 5, a part of the chip underside 32 can be modified so that the chip is wetted more effectively by the liquid 5 than the rest of the chip surface. How well the components are wetted by the liquid can be determined by measuring the contact angle of the liquid 5 on the respective parts of the surface.

Thin-film light-emitting diode chips (“thin-film LED chips” for short) can be mounted using the techniques described above. A thin-film LED chip is particularly distinguished by the following characteristics. A reflective layer is applied or formed onto a first main surface of an electromagnetic-radiation-generating sequence of epitaxy layers facing the substrate, and the reflective layer reflects at least some of the electromagnetic radiation back to the sequence of epitaxy layers. A basic principle of a thin-film LED is, for example, described in I. Schnitzer et al., Appl. Phys. Lett. 63 (16), Oct. 18, 1993, 2174-2176. In one implementation, the thin-film LED chip is a favorable approximation of a reflective Lambert surface.

The thickness of the sequence of epitaxy layers is 20 μm or less, such as about 10 μm. The sequence of epitaxy layers contains at least one semiconductor layer with at least one surface having a mixed structure which can produce a nearly ergodic distribution of light in the epitactic sequence of epitaxy layers, i.e., the surface manifests highly ergodic stochastic scattering behavior.

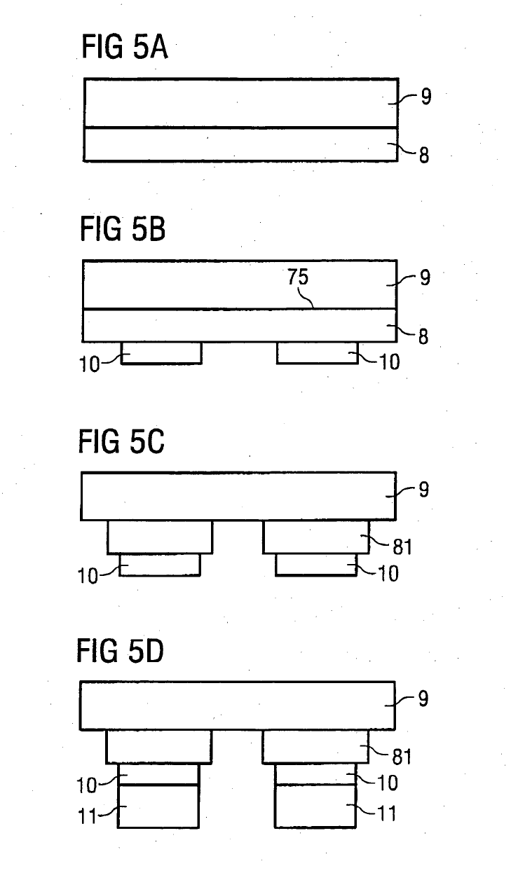

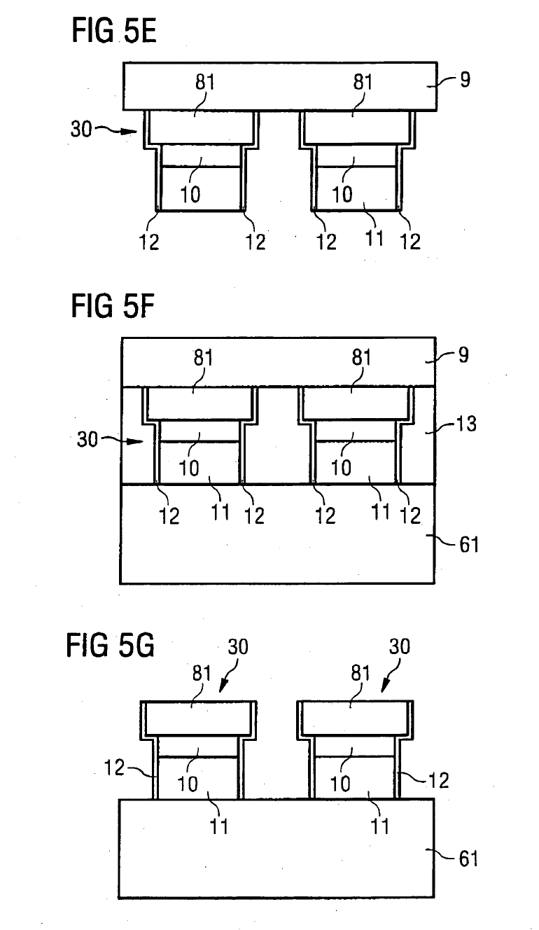

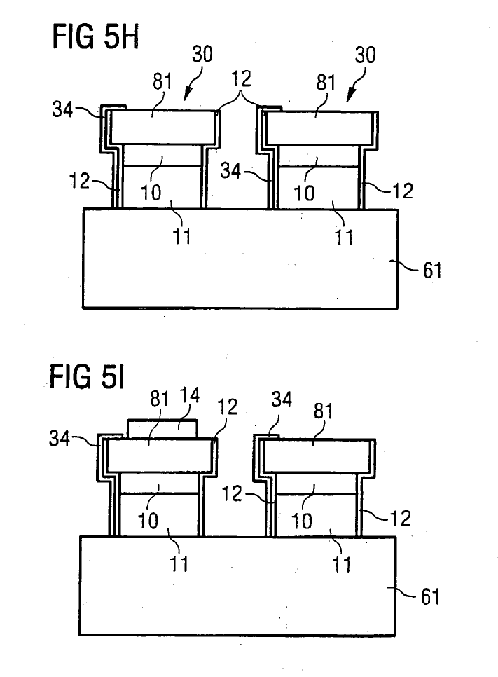

Referring to FIG. 5a, an active layer sequence 8 is epitaxially deposited onto a substrate 9. The substrate 9 can include sapphire.

In one implementation, the active sequence of epitaxy layers that can generate electromagnetic radiation is based on nitride compound semiconductors, such as gallium nitride semiconductor. The group of electromagnetic-radiation-generating epitaxy layer sequences based on a nitride compound semiconductor material includes semiconductor layer structures suitable for a radiation-emitting semiconductor component having a layer sequence of different individual layers. One of the layers can be a layer with a nitride compound semiconductor material, such as gallium nitride InₓAlYGa_{1 -x-y}N where 0≦x≦1, 0≦y≦1, and x+y≦1. This nitride compound semiconductor material does not necessarily have to have a mathematically precise composition according to the above formula. Rather, the material can have one or more dopants as well as additional components that do not essentially change the physical properties of the material. In addition to N and In, Al and/or Ga, the material can contain other elements.

Such a semiconductor structure can have a conventional pn junction, a double heterostructure, a single quantum well structure (SQW constructor), or a multiple quantum well structure (MQW structure).

Referring to FIG. 5b, an electrically conductive, reflective contact layer 10 is structured onto the active layer sequence 8. In the thin-film LED chip 30 (see FIG. 5g), the reflective contact layer 10 directs at least some of the light arising from the active layer sequence 8 toward the light emitting surface 75 of the thin-film LED chip 30. The reflective contact layer 10 also electrically contacts the active layer sequence 8.

Referring to FIG. 5c, grooves are then etched between the conductive, reflecting contact layers 10 in the active layer sequence 8, producing active layer stacks 81 on which the electrically conductive, reflective contact layer 10 is located.

Referring to FIG. 5d, a metallic reinforcing layer 11 is applied to the conductive, reflective contact layer 10 on the active layer stack 81. In some implementations, a galvanic process is used to apply the metal reinforcing layer 11.

Referring to FIGS. 5e-5f, a passivation layer 12 is subsequently applied over the metal reinforcing layer 11 and on the side surfaces of the future thin-film LED chips 30. The grooves between the future thin-film LED chips 30 are then filled with a polymer material 13. An auxiliary substrate 61 that can be selectively released from the polymer material 13 can also be applied.

Referring to FIG. 5g, the substrate 9 and the polymer material 13 are removed from the future semiconductor chip 30 and the auxiliary substrate 61, such as with a laser, so that the future thin-film LED chip 30 is on the auxiliary substrate 61.

Referring to FIG. 5h, an electrically-conductive layer 34 is applied over the passivation layer 12, such as on only one side of the future thin-film LED chips 30. The other side of the thin-film LED chips remains free of the electrically-conductive layer. In some implementations, a conductive layer 34 as an n-contact is only formed on one side of the thin-film LED chip, whereas the other side is covered with a passivation layer. The p-contact can be on the rear of the thin-film LED chip. The side length of such a thin-film LED chip 30 can be about 110 μm.

Forming the thin-film LED chip 30 as described above creates a vertical current path running from the top to the bottom of the chip. The passivation layer 12 on the side surfaces of the chip 30 ensures that current runs vertically through the chip 30. Electrical contact with the chip 30 can be made at the top of the chip, where the electrically-conductive layer 34 overlaps the top of the chip. The back side of the chip is electrically conductive.

Referring to FIG. 5i, the thin-film LED chips 30 can now be tested. If LED chips that generate mixed-color light are desired, the LED chips can be covered with wavelength conversion material 14. Such wavelength conversion materials 14 are, for example, described in WO 98/12757 A1.

In one implementation, the thin-film LED chips 30 are separated by dissolving the auxiliary substrate 61 in a suitable liquid 5. The thin-film LED chips 30 are only exposed to a slight mechanical stress, and there is little to no loss of material as can occur in sawing.

A mounting procedure as described above can seamlessly follow the manufacturing steps for forming the thin-film LED chips.

The thin-film LED chips 30 manufactured by the above described method are suitable for electrical contacting, such as with the method described in FIGS. 3a-3c. The thin-film LED chips manufactured as described above can eliminate the need for bond pads and shadow effects can therefore be avoided. This is due at least in part to the passivation layer 12 on both sides of the chip and the electrically-conductive layer 34 on one side of the chip 30, over the passivation layer 12 and on a part of the top surface of the chip 30. The top surface of the chip 30, here, is the radiation emitting side of the chip 30. These features allow for electrical connection on the top of the chip by metal-containing particles in the liquid. Thus, the vertical current path running from the top to the bottom of the thin-film LED chip 30, the electrically-conductive layer 34 on one side of the thin-film LED chip 30 and the passivation layer 12 on the other side of the thin-film LED chip 30 allow for dispensing with bond pads.

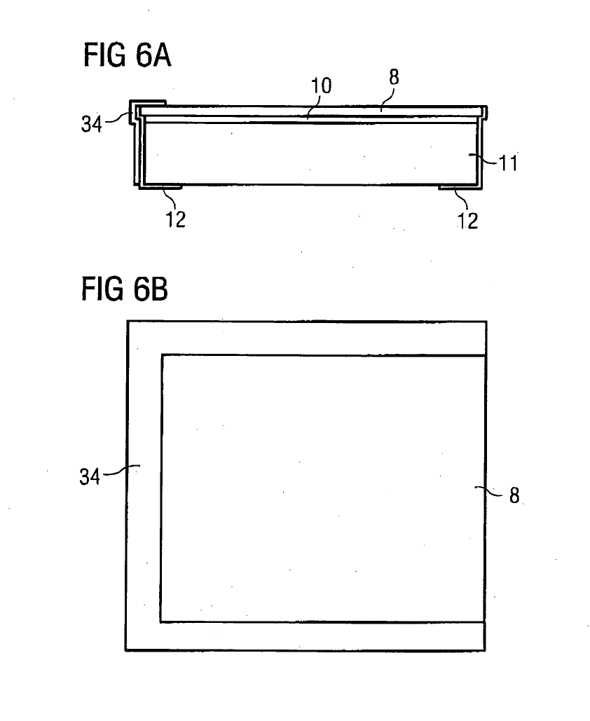

Referring to FIG. 6a, the metal conductive reinforcing layer 11 and the conductive reflective contact layer 10 create an electrical contact on the bottom of the thin-film LED chip 30 through suitably conductive structures 21 on the substrate 2.

Referring to FIG. 6b, the top of the thin-film LED chip 30 can be electrically contacted using metal-containing particles that are in the liquid 5 together with the thin-film LED chip 30. The metal containing particles deposit on the sides of the semiconductor chip 3 as the liquid drop 51 dries. An electrical contact is created via the electrically conductive layer 34 on one side of the chip. Because the passivation layer 12 is on the other side of the chip 30, the passivation layer 12 prevents a short-circuit from occurring. The back side of the chip 30 can be electrically coupled to electrically conductive structures on the substrate.

For the sake of completeness, it is noted that the invention is not restricted to the exemplary embodiments described herein. All embodiments that are based upon the underlying principle explained herein fall within the scope of the invention. The different elements of the various exemplary embodiments can also be combined with each other.

All references disclosed herein are incorporated in their entirety by reference. The disclosures of German Application Serial No. 10 2004 031 734.8, filed Jun. 30, 2004, and German Application Serial No. 10 2004 044 179.0, filed Sep. 13, 2004 are considered part of and are incorporated by reference in the disclosure of this application.

What is claimed is:

1. A method for applying semiconductor chips (3) to a substrate (2), comprising:
applying molecules of a first type (1) to a substrate (2) surface on which semiconductor chips (3) are to be applied;
applying molecules of a second type (4) to a surface of a semiconductor chip (3), wherein the molecules of the second type are configured to bond to the molecules of the first type (1);
introducing the semiconductor chip (3) into a liquid (5);
positioning a drop (51) of the liquid (5) with not more than one semiconductor chip (3) on the substrate (2); and
evaporating the drop (51) of liquid (5) from the substrate (2), leaving the semiconductor chip on the substrate (2).

2. The method of claim 1, wherein positioning a drop (51) of the liquid (5) includes positioning a plurality of drops, and wherein each drop has no more than one semiconductor chip (3).

3. The method of claim 1, further comprising electrically contacting the semiconductor chip (3) with an electrically conductive structure (21) on the substrate (2).

4. The method of claim 1, wherein the semiconductor chip (3) is applied to a soluble auxiliary substrate (6) and introduced into the liquid (5) by dissolving the auxiliary substrate (6).

5. The method of claim 4, wherein the liquid (5) contains the molecules of the second type (4) and the molecules of the second type (4) adsorb onto the semiconductor chip (3) after the semiconductor chip (3) is introduced into the liquid (5).

6. The method of claim 1, wherein the molecules of the second type (4) are applied to the semiconductor chip (3) by stamping, printing or photolithography.

7. The method of claim 1, wherein the molecules of the first type (1) are adsorbed on the substrate (2) from a solution.

8. The method of claim 1, wherein the molecules of the first type (1) are applied to the substrate by one of stamping, printing or photolithography.

9. The method of claim 1, wherein the drop (51) is deposited on the substrate (2) by an inkjet system.

10. The method of claim 1, wherein a cell sorting system ensures that not more than one semiconductor chip (3) is in a drop (51).

11. The method of claim 1, wherein metal-containing particles (7) are added to the liquid (5) with the semiconductor chip (3) and the particles electrically connect the semiconductor chips (3) with electrically conductive structures (21) of the substrate (2) after the liquid (5) dries.

12. The method of claim 1, further comprising modifying a part of the surface of the substrate (2) of such that the part is wetted more effectively by the liquid (5) in which the semiconductor chip (3) is introduced than the rest of the surface of the substrate (2).

13. The method of claim 1, further comprising modifying a part of the surface of the semiconductor chip (3) such that the part of the surface is wetted more effectively by the liquid (5) than the remaining surface of the respective semiconductor chip (3).

14. The method of claim 1, wherein the semiconductor chip (3) is a thin-film LED chip (30).

15. The method of claim 14, further comprising forming the thin-film LED chip (30), including the steps of:
forming an active layer sequence (8) suitable to generate electromagnetic radiation on a chip substrate (9);
forming a structured, electrically-conductive reflective contact layer (10) on the active layer sequence (8);
structuring the active layer sequence (8) into separate, active stacks of layers (81) on the chip substrate (9), thereby forming gaps;
applying an electrically-conductive reinforcing layer (11) on the reflective contact layer (10);
forming a passivation layer (12) on the side surfaces of the active stack of layers (81) and reflective contact layer (10) and at least parts of the electrically-conductive reinforcing layer (11);
filling the gaps with a filler (13);
applying an auxiliary substrate layer (61) on the reinforcing layer (11);
removing of the chip substrate (9) and the filler (13); and
applying an electrically-conductive layer (34) on one side of the active stack of layers (81), the reflective contact layer 10 and the electrically-conductive reinforcing layer ( 11) and on a portion of an exposed surface of the active layer stack.

16. The method of claim 15, wherein metal-containing particles (7) are added to the liquid (5) with the semiconductor chip (3) and the particles electrically connect the semiconductor chips (3) with electrically conductive structures (21) of the substrate (2) after the liquid (5) dries.

17. The method of claim 16, wherein the substrate (2) includes a printed circuit board.
